(19) United States
(12) Patent Application Publication
(10) Pub. No.: US 2014/0002202 A1
(43) Pub. Date: Jan. 2, 2014

(54) VIBRATORY DEVICE AND ELECTRONIC APPARATUS

(71) Applicant: Seiko Epson Corporation, Tokyo (JP)

(72) Inventor: Toshiyuki Nozawa, Okaya (JP)

(21) Appl. No.: 13/926,110

(22) Filed: Jun. 25, 2013

(30) Foreign Application Priority Data
Jun. 28, 2012 (JP) 2012-145110

(51) Int. Cl. H03B 5/30

(52) U.S. Cl. CPC H03B 5/30
USPC 331/156

(57) ABSTRACT

A vibratory device includes a vibrator including a beam, which can be displaced with respect to a substrate, movable electrodes each having a comb-like shape, the comb teeth extending from the beam, and stationary electrodes fixed to the substrate and each having a comb-like shape, each of the comb teeth being inserted between the comb-like electrodes of the movable electrodes, an oscillator circuit adapted to make the vibrator oscillate, and a bias circuit adapted to apply a direct-current bias voltage between the movable electrodes and the stationary electrodes.

### BACKGROUND

1. Technical Field

The present invention relates to a vibratory device, an electronic device, and so on.

2. Related Art

An oscillator using the micro electro-mechanical system (MEMS) technology, and having an MEMS element provided to a semiconductor substrate is known generally. In such an oscillator, the MEMS element is used as a vibrator, and a clock pulse with a target frequency is output to an external circuit and so on. Including such an MEMS oscillator, a device including a vibrator (or a vibrator plate), a necessary oscillator circuit, and so on, and outputting a clock pulse with a target frequency to the outside is hereinafter referred to as a vibratory device. Further, the MEMS element used as the vibrator is hereinafter referred to as an MEMS vibrator.

As the MEMS vibrator in the related art, there is known a device provided with a movable electrode held by a support member in a state of floating on a substrate, and a stationary electrode disposed at a slight distance from the movable electrode, and having the movable electrode vibrating in response to an alternating voltage applied between these electrodes (see, e.g., JP-A-2010-232791).

It is possible to configure the vibratory device (the MEMS oscillator) by combining the MEMS vibrator with an oscillator circuit. The alternating voltage is applied by the oscillator circuit, and the oscillator circuit can keep the oscillation of the movable electrode at a frequency determined by the resonant frequency. Therefore, the vibratory device can generate a signal with a stable frequency.

However, due to, for example, a variation in the dimension of the movable electrode, a variation in the resonant frequency of the MEMS vibrator occurs generally. Therefore, it is necessary to correct the variation in the resonant frequency in some way. JP-A-2010-232791 discloses an invention of a method of regulating the oscillation frequency of the oscillator by applying a direct-current bias voltage between the stationary electrode and the movable electrode of the vibrator. Further, JP-A-2010-011134 discloses an invention of a method of correcting the variation in the resonant frequency by applying a tensile stress to a vibrating body (corresponding to the movable electrode).

However, in the invention of JP-A-2010-232791, the movable electrode and the stationary electrode are arranged to form a parallel plate structure, and therefore, the electrostatic force acting between the electrodes is nonlinear. Therefore, there is a problem that in the case of drastically changing the resonant frequency by the bias voltage, the force is changed dramatically in response to the change in the voltage, and the action nonlinear to the displacement of the movable electrode becomes conspicuous.

Further, in the invention of JP-A-2010-011134, although the problem of the increase in the nonlinear action due to the regulation of the resonant frequency described above can be suppressed, it is required to additionally provide an electrode for generating the tensile stress separately on the same plane with the vibrator. Therefore, there is a problem that the size of the vibratory device grows.

### SUMMARY

An advantage of some aspects of the invention is to provide a vibratory device making it possible to regulate the frequency without the nonlinear action of the movable electrode and the increase in the size of the vibratory device.

The invention can be implemented as the following forms or application examples.

### APPLICATION EXAMPLE 1

This application example is directed to a vibratory device including a vibrator including a beam, which can be displaced with respect to a substrate, a movable electrode having a comb-like shape, the comb teeth extending from the beam, and a stationary electrode fixed to the substrate and having a comb-like shape, each of the comb teeth being inserted between the comb-like electrode of the movable electrode, an oscillator circuit adapted to make the vibrator oscillate, and a bias circuit adapted to apply a direct-current bias voltage between the movable electrode and the stationary electrode.

### APPLICATION EXAMPLE 2

The vibratory device according to the above application example may be configured such that the movable electrode includes a first movable electrode having a comb-like shape disposed on one side of the beam in a plan view, and a second movable electrode having a comb-like shape disposed on the other side of the beam, the stationary electrode includes a first stationary electrode having a comb-like shape, each of the comb teeth being inserted between the comb teeth of the first movable electrode, and a second stationary electrode having a comb-like shape, each of the comb teeth being inserted between the comb teeth of the second movable electrode, and the bias circuit includes a first bias circuit adapted to apply a direct-current bias voltage between the first movable electrode and the first stationary electrode, and a second bias circuit adapted to apply a direct-current bias voltage between the second movable electrode and the second stationary electrode.

### APPLICATION EXAMPLE 3

The vibratory device according to the above application example may be configured such that in the vibrator the first movable electrode and the second movable electrode of the movable electrode are electrically connected to each other, and the first stationary electrode and the second stationary electrode of the stationary electrode are electrically isolated from each other.

### APPLICATION EXAMPLE 4

The vibratory device according to the above application example may be configured such that in the vibrator the first movable electrode and the second movable electrode of the movable electrode are electrically isolated from each other, and the first stationary electrode and the second stationary electrode of the stationary electrode are electrically connected to each other.

### APPLICATION EXAMPLE 5

The vibratory device according to the above application example may be configured such that both ends of the beam of the vibrator are fixed to the substrate.

The vibratory device according to any of the application examples includes the vibrator having the beam displaceable with respect to the substrate, the movable electrode having a comb-like shape, the comb teeth extending from the beam, and the stationary electrode fixed to the substrate and having a comb-like shape, the oscillator circuit adapted to make the vibrator oscillate, and the bias circuit adapted to apply the direct-current bias voltage between the movable electrode and the stationary electrode. Here, in the vibrator, the comb-like electrodes of the stationary electrode are inserted between the comb-like electrodes of the movable electrode. Therefore, there is configured a so-called comb drive actuator having the movable electrode displaced by the electrostatic force acting between the both electrodes due to the direct-current bias voltage applied by the bias circuit.

For example, when the movable electrode is attracted by the electrostatic force toward the stationary electrode, since the tensile stress is applied to the beam for supporting the movable electrode, the resonant frequency of the movable electrode rises. Therefore, the vibratory device according to any one of these application examples is capable of regulating the resonant frequency by the bias circuit regulating the direct-current bias voltages to be applied between the movable electrode and the stationary electrode.

On this occasion, since the movable electrode and the stationary electrode do not form the parallel plate structure as in the case of the invention disclosed in JP-A-2010-232791, the problem that the nonlinear action becomes conspicuous in accordance with the displacement of the movable electrode does not occur. Further, since the movable electrode and the stationary electrode attract each other, it is not required to separately provide an electrode for generating the tensile stress. In other words, the problem that the vibratory device grows in size does not occur. Therefore, the vibratory device according to any one of these application examples is capable of regulating the frequency without the nonlinear action of the movable electrode, and without increasing the size of the vibratory device.

Here, although the movable electrode of the vibrator is supported by the beam having elasticity, the movable electrode can be provided with the comb-like electrodes extending on both sides of the beam in a plan view. In this case, it results that the movable electrode includes the first movable electrode having the comb-like electrodes disposed on one side and the second movable electrode having the comb-like electrodes disposed on the other side. Further, the stationary electrode can also include the first stationary electrode having a comb-like shape, each of the comb teeth being inserted between the comb teeth of the first movable electrode, and the second stationary electrode having a comb-like shape, each of the comb teeth being inserted between the comb teeth of the second movable electrode.

In the case of such a configuration as described above, it is possible for the bias circuit to apply the direct-current bias voltages independently between the first movable electrode and the first stationary electrode, and between the second movable electrode and the second stationary electrode. Therefore, the tensile stress applied to the beam can be regulated by the difference between the direct-current bias voltages, and as a result, the regulation range of the resonant frequency of the movable electrode can be broadened.

Further, it is also possible that the first movable electrode and the second movable electrode are electrically connected to each other, while the first stationary electrode and the second stationary electrode are electrically isolated from each other. In this case, it is possible to apply the direct-current bias voltages independent of each other to the first stationary electrode and the second stationary electrode, and it is also possible to apply the alternating-current voltages with the respective phases 180 degrees different from each other. Therefore, the resonant frequency can be regulated in a wide range, and the movable electrode can be vibrated with a large amplitude due to the alternating-current voltage.

Here, to the contrary, it is also possible that the first movable electrode and the second movable electrode are electrically isolated from each other, while the first stationary electrode and the second stationary electrode are electrically connected to each other. Also in this case, the resonant frequency can be regulated in a wide range, and the movable electrode can be vibrated with a large amplitude due to the alternating-current voltage.

Further, the vibrator can have a fixed-fixed beam structure in which the both ends of the beam are fixed to the substrate. By adopting the fixed-fixed beam structure, the tensile stress can efficiently be applied to the beam, and thus, the resonant frequency can be regulated in a wide range.

### APPLICATION EXAMPLE 6

This application example is directed to a vibratory device including a vibrator including a beam having one end fixed to a substrate and displaceable with respect to the substrate, a movable electrode having a comb-like shape, the comb teeth extending from the beam, and a stationary electrode fixed to the substrate and having a comb-like shape, each of the comb teeth being inserted between the comb-like electrode of the movable electrode, an oscillator circuit adapted to make the vibrator oscillate, and a bias circuit adapted to apply a direct-current bias voltage between the movable electrode and the stationary electrode, and the stationary electrode includes a third stationary electrode disposed on one side of an electrode constituting the movable electrode.

### APPLICATION EXAMPLE 7

The vibratory device according to the above application example maybe configured such that the stationary electrode includes a fourth stationary electrode disposed on the other side of the electrode constituting the movable electrode, the third stationary electrode and the fourth stationary electrode are electrically isolated from each other, and the bias circuit includes a third bias circuit adapted to apply a direct-current bias voltage between the movable electrode and the third stationary electrode, and a fourth bias circuit adapted to apply a direct-current bias voltage between the movable electrode and the fourth stationary electrode.

The vibratory device according to any of the application examples includes the vibrator having the movable electrode displaceable with respect to the substrate, and the stationary electrode fixed to the substrate, the oscillator circuit adapted to make the vibrator oscillate, and the bias circuit adapted to apply the direct-current bias voltage between the movable electrode and the stationary electrode. Here, the movable electrode is supported by the beam having elasticity and one end fixed to the substrate. Further, the stationary electrode includes the third stationary electrode having a comb-like shape, each of the teeth being inserted on one side (e.g., the far side from the fixation portion of the beam with respect to the comb-like electrodes of the movable electrode) of the electrode constituting the movable electrode. Therefore, there is configured a so-called comb drive actuator having the movable electrode displaced in one direction (e.g., the direction of getting further from the fixation portion of the beam) by the electrostatic force acting between the both electrodes due to the direct-current bias voltage applied by the bias circuit.

For example, when the movable electrode is attracted by the electrostatic force toward the stationary electrode (here, the third stationary electrode), since the tensile stress is applied to the beam for supporting the movable electrode, the resonant frequency of the movable electrode rises. Therefore, the vibratory device according to any one of these application examples is capable of regulating the resonant frequency by the bias circuit regulating the direct-current bias voltages to be applied between the movable electrode and the stationary electrode.

On this occasion, since the movable electrode and the stationary electrode do not form the parallel plate structure as in the case of the invention disclosed in JP-A-2010-232791, the problem that the nonlinear action becomes conspicuous in accordance with the displacement of the movable electrode does not occur. Further, since the movable electrode and the stationary electrode attract each other, it is not required to separately provide an electrode for generating the tensile stress. In other words, the problem that the vibratory device grows in size does not occur.

Therefore, the vibratory device according to any one of these application examples is capable of regulating the frequency without the nonlinear action of the movable electrode, and without increasing the size of the vibratory device. Further, by adopting the cantilever structure, the vibrator can use a variety of shapes of movable electrodes, and a flexible design becomes possible.

Here, the stationary electrode can include the fourth stationary electrode having comb-like electrodes inserted on the other side (e.g., the near side to the fixation portion of the beam) different from the case of the third stationary electrode with respect to the comb-like electrodes of the movable electrode. In this case, the third stationary electrode and the fourth stationary electrode are electrically isolated from each other, and the bias circuit can apply the direct-current bias voltages independent of each other between the movable electrode and the third stationary electrode and between the movable electrode and the fourth stationary electrode, respectively. Therefore, the tensile stress or the compressive stress applied to the beam can be regulated by the difference between the direct-current bias voltages, and as a result, the regulation range of the resonant frequency of the movable electrode can be broadened.

### APPLICATION EXAMPLE 8

This application example is directed to an electronic apparatus including the vibratory device according to the application example described above.

The vibratory device according to the application example described above is capable of regulating the frequency without the nonlinear action of the movable electrode, and without increasing the size of the vibratory device. Therefore, the electronic apparatus according to the present application example equipped with the vibratory device according to any one of the application examples described above is capable of acting based on the clock pulses with a desired accurate frequency while achieving a small size. For example, in the case of adopting a watch as the electronic apparatus, the size can be reduced, and it becomes possible to display the time with high accuracy.

### BRIEF DESCRIPTION OF THE DRAWINGS

The invention will be described with reference to the accompanying drawings, wherein like numbers reference like elements.

FIG. 1 is a block diagram of a vibratory device according to a first embodiment.

FIG. 2 is a plan view schematically showing an MEMS vibrator of the vibratory device according to the first embodiment.

FIG. 3 is a side view schematically showing the MEMS vibrator of the vibratory device according to the first embodiment.

FIG. 4 is a diagram schematically showing deformation of a movable electrode in the vibratory device according to the first embodiment.

FIG. 5 is a diagram for explaining an electrostatic force between comb-like electrodes.

FIG. 6 is a diagram for explaining a circuit configuration example of the vibratory device according to the first embodiment.

FIG. 7 is a plan view schematically showing the MEMS vibrator of a vibratory device according to a first modified example.

FIG. 8 is a plan view schematically showing an MEMS vibrator of a vibratory device according to a second modified example.

FIG. 9 is a diagram for explaining a circuit configuration example of the vibratory device according to the second modified example.

FIG. 10 is a plan view schematically showing an MEMS vibrator of a vibratory device according to a second embodiment.

FIG. 11 is a side view schematically showing the MEMS vibrator of the vibratory device according to the second embodiment.

FIG. 12 is a diagram schematically showing a vibration of a movable electrode in the vibratory device according to the second embodiment.

FIG. 13 is a diagram for explaining a circuit configuration example of the vibratory device according to the second embodiment.

FIG. 14 is a plan view schematically showing an MEMS vibrator of a vibratory device according to a third modified example.

FIG. 15 is a side view schematically showing the MEMS vibrator of the vibratory device according to the third modified example.

FIG. 16 is a block diagram of an electronic apparatus according to an application example.

FIGS. 17A through 17C are diagrams each showing an example of an appearance of an electronic apparatus.

FIG. 18 is a plan view schematically showing a vibrator including parallel plate electrodes.

FIG. 19 is a side view schematically showing the vibrator including the parallel plate electrodes.

FIG. 20 is a diagram for explaining an electrostatic force between the parallel plate electrodes.

### DESCRIPTION OF EXEMPLARY EMBODIMENTS

Hereinafter, some preferred embodiments of the invention will be described in detail with reference to the accompanying drawings. It should be noted that the embodiments described below do not unreasonably limit the contents of the invention as set forth in the appended claims. Further, all of the components described below are not necessarily essential elements of the invention.

### 1. First Embodiment

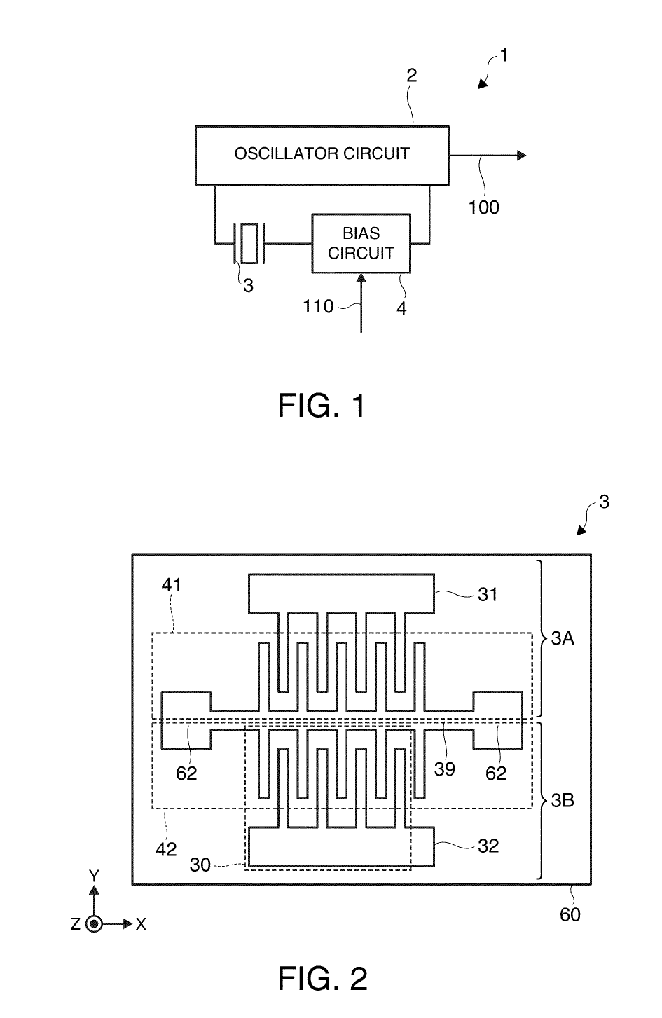

FIG. 1 is a block diagram of a vibratory device 1 according to the present embodiment. The vibratory device 1 includes an oscillator circuit 2, a vibrator 3, and a bias circuit 4. In the present embodiment, the vibrator 3 is formed of an MEMS vibrator, and provided with a movable electrode and a stationary electrode as described later. The bias circuit 4 applies a direct-current bias voltage between the movable electrode and the stationary electrode to thereby regulate the resonant frequency of the vibrator 3. Further, the oscillator circuit 2 is formed of a circuit for oscillating the vibrator 3.

The bias circuit 4 controls the direct-current bias voltage to be applied between movable electrode and the stationary electrode based on a control signal 110 received. Further, the oscillator circuit 2 outputs clock pulses 100 with the target frequency to, for example, a circuit located inside or outside the vibratory device 1.

FIG. 2 is a plan view schematically showing the vibrator 3 of the vibratory device 1 according to the present embodiment. It should be noted that for the use in the explanation of the MEMS vibrator and the electrostatic force between the electrodes, three axes (an X axis, a Y axis, and a Z axis) perpendicular to each other are shown in the drawings on and after FIG. 2 if necessary. FIG. 2 is a plan view of the vibrator 3 viewed from the positive direction of the Z axis.

As shown in FIG. 2, the vibrator 3 is provided with the stationary electrode and the movable electrode disposed above a substrate 60. In the present embodiment, the stationary electrode includes a first stationary electrode 31 and a second stationary electrode 32 fixed on the substrate 60. The first stationary electrode 31 and the second stationary electrode 32 are arranged so as to be opposed to each other having a beam 39 for supporting the movable electrode sandwiched therebetween. The first stationary electrode 31 and the second stationary electrode 32 are each provided with comb-like electrodes each extending toward the beam 39 and perpendicular to the longitudinal direction of the beam 39.

The movable electrode is supported by the beam 39 having elasticity, and can be displaced with respect to the substrate 60. In the present embodiment, it is assumed that the beam 39 is formed integrally with the movable electrode. Further, fixation portions 62 corresponding to both of the ends of the beam 39 are fixed to the substrate 60, and thus, the movable electrode has a fixed-fixed beam structure.

The movable electrode has comb-like electrodes inserted between the comb-like electrodes of the first stationary electrode 31. Specifically, the movable electrode has the comb-like electrodes, which extend from the beam 39 in the positive direction of the Y axis in the plan view of FIG. 2, and are inserted between the comb-like electrodes of the first stationary electrode 31. Here, apart of the movable electrode including the electrodes extending from the beam 39 in the positive direction of the Y axis is defined as a first movable electrode 41.

Further, the movable electrode has comb-like electrodes inserted between the comb-like electrodes of the second stationary electrode 32. Specifically, the movable electrode has the comb-like electrodes, which extend from the beam 39 in the negative direction of the Y axis in the plan view of FIG. 2, and are inserted between the comb-like electrodes of the second stationary electrode 32. Here, apart of the movable electrode including the electrodes extending from the beam 39 in the negative direction of the Y axis is defined as a second movable electrode 42. It should be noted that although the first stationary electrode 31 partially enters the first movable electrode 41, and the second stationary electrode 32 partially enters the second movable electrode 42 in FIG. 2 for the sake of convenience of drawing, the first movable electrode 41 and the second movable electrode 42 are each a part of the movable electrode, and do not include the stationary electrode.

The first movable electrode 41 and the second movable electrode 42 are electrically connected to each other. On the other hand, the first stationary electrode 31 and the second stationary electrode 32 are electrically isolated from each other. Therefore, it is possible to apply an alternating-current voltage and a direct-current bias voltage independently between the first movable electrode 41 and the first stationary electrode 31, and between the second movable electrode 42 and the second stationary electrode 32. Therefore, it can be said that the vibrator 3 of the vibratory device 1 according to the present embodiment is configured including such two vibrators 3A, 3B as shown in FIG. 2.

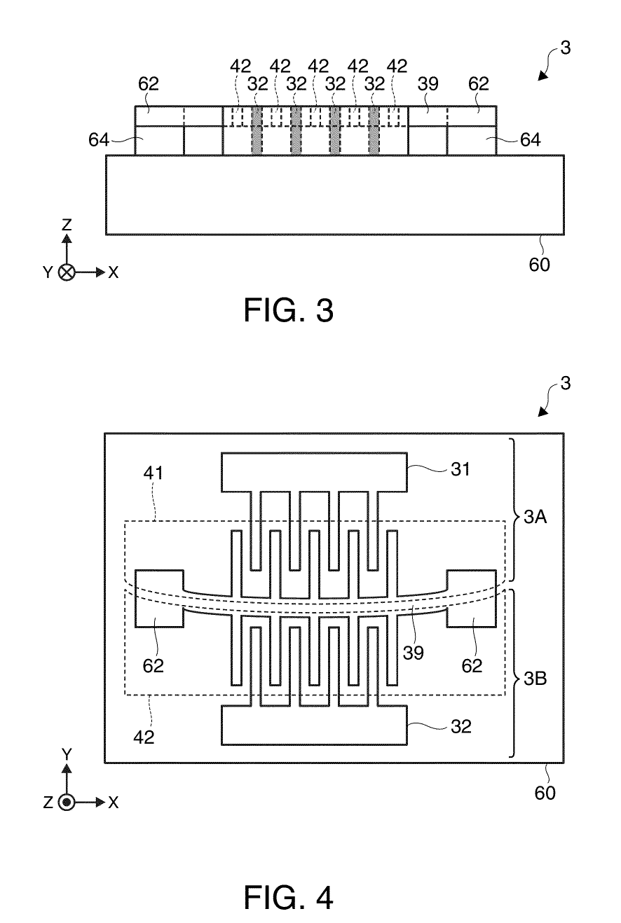

FIG. 3 is a side view schematically showing the vibrator 3 of the vibratory device 1 according to the present embodiment viewed from the negative direction of the Y axis. FIG. 3 corresponds to a side view of the first stationary electrode 31 viewed from the second stationary electrode 32 side shown in FIG. 2. It should be noted that the comb-like electrodes are indicated by the dotted lines as a partially transparent view.

As shown in FIG. 3, the movable electrode is disposed above the substrate 60 with a gap. The beam 39 for supporting the movable electrode is fixed to the substrate 60 in the fixation portions 62 using support members 64. As shown in FIG. 3, the movable electrode has the gap corresponding to the height of the support members 64, and is therefore allowed to be displaced in a direction (e.g., the Y direction) other than the X direction.

The comb-like electrodes of the movable electrode (the second movable electrode 42 in FIG. 3) and the comb-like electrodes of the stationary electrode (the second stationary electrode 32 in FIG. 3) are inserted alternately to each other as shown in FIG. 3 to thereby form a comb drive actuator having the movable electrode moving in accordance with the voltage applied between the electrodes.

FIG. 4 is a diagram schematically showing deformation of a movable electrode in the vibratory device 1 according to the present embodiment. Specifically, FIG. 4 shows a state in which a tensile stress is applied to the beam for supporting the movable electrode by applying the direct-current bias voltage, and thus the beam 39 is deformed to approach the second stationary electrode 32. Further, the alternating-current voltages having phases 180 degrees different from each other are applied by the oscillator circuit 2 (see FIG. 1) respectively to the first stationary electrode 31 and the second stationary electrode 32, and thus, the movable electrode shown in FIG. 4 vibrates in the Y-axis direction. It should be noted that the same components as those shown in FIG. 2 are denoted with the same reference numerals, and the explanation thereof will be omitted.

Here, the direct-current bias voltage will be explained in detail. In the present embodiment, the bias circuit 4 (see FIG. 1) includes a first bias circuit (not shown) and a second bias circuit (not shown) independent of each other, wherein the first bias circuit applies a direct-current bias voltage between the first movable electrode 41 and the first stationary electrode 31, and the second bias circuit applies a direct-current bias voltage between the second movable electrode 42 and the second stationary electrode 32. In this case, the first bias circuit and the second bias circuit are capable of applying the direct-current bias voltages in an independent manner.

Since the electrostatic force described later acts due to the direct-current voltage applied, it results that the movable electrode is steadily attracted toward the stationary electrode (the second stationary electrode 32 in the example shown in FIG. 4) with a larger electrical potential difference. Further, since the alternating-current voltages having the phases 180 degrees different from each other are respectively applied to the first stationary electrode 31 and the second stationary electrode 32, the movable electrode vibrates with a large amplitude at the resonant frequency.

Here, compared to the state (see FIG. 2) in which no direct-current bias voltage is applied, since the tensile stress is applied to the beam 39, which is integrated with the movable electrode and supports the movable electrode, the resonant frequency of the movable electrode rises. In other words, it becomes possible to regulate the resonant frequency of the movable electrode in accordance with the difference between the direct-current bias voltages applied by the first bias circuit and the second bias circuit. Since the regulation can be performed using the difference in voltage between the two independent bias circuits (the first bias circuit and the second bias circuit) instead of a single bias circuit, the regulation range of the resonant frequency of the movable electrode can be broadened.

Further, the comb drive actuator, which has the comb-like electrodes of the movable electrode and the comb-like electrodes of the stationary electrode inserted alternately to each other, and has the movable electrode moved in accordance with the voltage applied between these electrodes, is configured in the vibrator 3. The advantage of this configuration will hereinafter be explained.

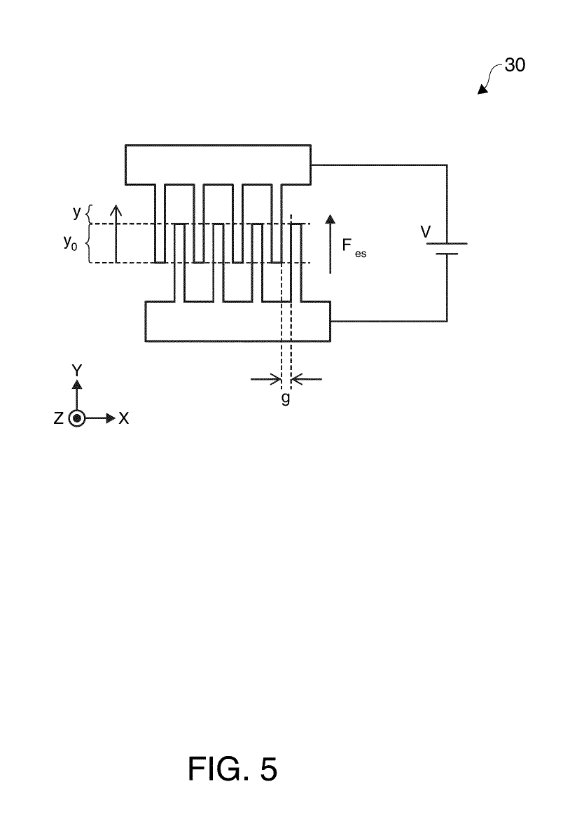

FIG. 5 is a diagram for explaining the electrostatic force between the comb-like electrodes inserted alternately to each other. It should be noted that electrodes 30 shown in FIG. 5 correspond to electrodes 30 constituting a part of the vibrator 3 shown in FIG. 2, and the explanation will be presented assuming that the upper electrode corresponds to the movable electrode and the lower electrode corresponds to the stationary electrode in FIG. 5.

In FIG. 5, the electrostatic force Fₑₛ directed toward the positive side of the Y axis is considered. Assuming that the height (in the Z-axis direction in FIG. 5) of the comb-like electrodes is “h,” the distance (in the X-axis direction in FIG. 5) between the comb-like electrodes is “g,” the initial overlapping length in the Y-axis direction between the comb-like electrodes is “y₀,” the displacement of the comb-like electrodes of the movable electrode in the positive direction of the Y axis is “y,” and the “n” pairs of comb-like electrodes are opposed to each other, the electrostatic force Fₑₛ is expressed by Formula (1) below.

$${F}_{es} = - \frac{{ɛ}_{r} {ɛ}_{0} {nhV}^{2}}{2 g} \qquad ( 1 )$$

Here, “ε₀” represents the vacuum permittivity, and “εᵣ” represents the relative permittivity of a substance filling the space between the electrodes. Further, “V” represents the electrical potential difference between the electrodes. As shown in Formula (1), the electrostatic force Fₑₛ does not have dependency on the displacement y and the initial overlapping length y₀. This means that by adopting the structure using the comb-like electrodes inserted alternately to each other, no influence of the nonlinear action occurs even in the case of performing the frequency regulation.

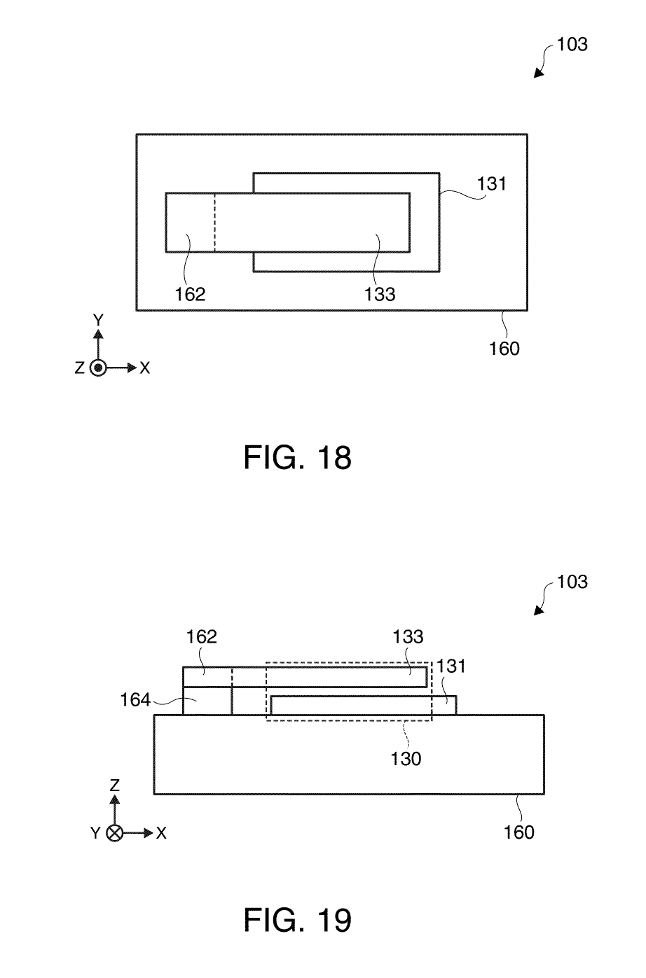

In order to explain this phenomenon in detail, the electrostatic force between parallel plate electrodes to be a comparative example will be obtained. FIG. 18 is a plan view schematically showing a vibrator 103 including the parallel plate electrodes. FIG. 18 is a view of the vibrator 103 viewed from the positive direction of the Z axis.

The vibrator 103 of the comparative example is provided with the stationary electrode 131 and the movable electrode 133 disposed above a substrate 160. Although the stationary electrode 131 is fixed on the substrate 160, the movable electrode 133 has a cantilever structure having a fixation portion 162 fixed to the substrate 160 and the other portion disposed above the substrate 160 with a gap.

FIG. 19 is a side view schematically showing the vibrator 103 including the parallel plate electrodes. As described above, the stationary electrode 131 is fixed above the substrate 160, and the movable electrode 133 is fixed to the substrate 160 in the fixation portion 162 using the support member 164.

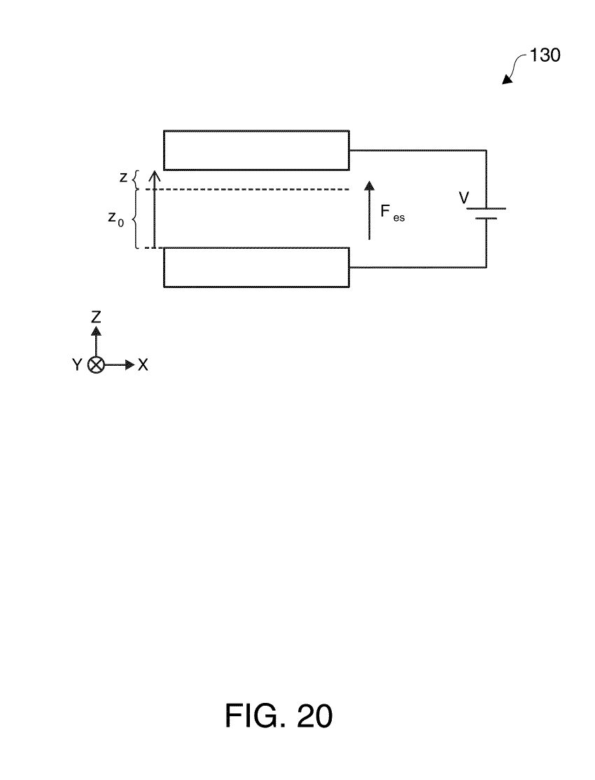

FIG. 20 is a diagram for explaining an electrostatic force between the parallel plate electrodes. It should be noted that electrodes 130 shown in FIG. 20 correspond to the electrodes 130 constituting a part of the vibrator 103 shown in FIG. 19, and the explanation will be presented assuming that the upper electrode corresponds to the movable electrode and the lower electrode corresponds to the stationary electrode in FIG. 20.

In FIG. 20, the electrostatic force Fₑₛ directed toward the positive side of the Z axis is considered. Assuming that the area of the parallel plate electrodes opposed to each other is “A,” the initial distance between the parallel plate electrodes in the Z-axis direction is “z₀,” and the displacement of the movable electrode in the positive direction of the Z axis is “z,” the electrostatic force Fₑₛ is expressed by Formula (2) below. It should be noted that the area A is obtained from the length of the side of the electrode in the X-axis direction and the side thereof in the Y-axis direction in FIG. 20.

$${F}_{es} = - \frac{A {ɛ}_{r} {ɛ}_{0} {V}^{2}}{2 {( {z}_{0} + z )}^{2}} \qquad ( 2 )$$

Here, similarly to Formula (1), “ε₀” represents the vacuum permittivity, “εᵣ” represents the relative permittivity of a substance filling the space between the electrodes and “V” represents the electrical potential difference between the electrodes. In such parallel plate electrodes as in the comparative example, the electrostatic force Fₑₛ acting between the electrodes is nonlinear as is obvious from Formula (2), and if the resonant frequency is substantially changed with the bias voltage, the force changes dramatically in response to the change in the voltage, and it results that the nonlinear action becomes conspicuous.

In contrast, in the comb-like electrodes inserted alternately to each other as in the case of the present embodiment, the electrostatic force Fₑₛ acting between the electrodes does not have the dependency on the displacement y (corresponding to the displacement z in Formula (2)) as shown in Formula (1). Therefore, the vibrator 3 of the vibratory device 1 according to the present embodiment does not have the problem that the nonlinear action is conspicuous in accordance with the displacement of the movable electrode. Further, since the movable electrode and the stationary electrode attract each other, it is not required to separately provide an electrode for generating the tensile stress. In other words, the problem that the vibratory device 1 grows in size does not occur.

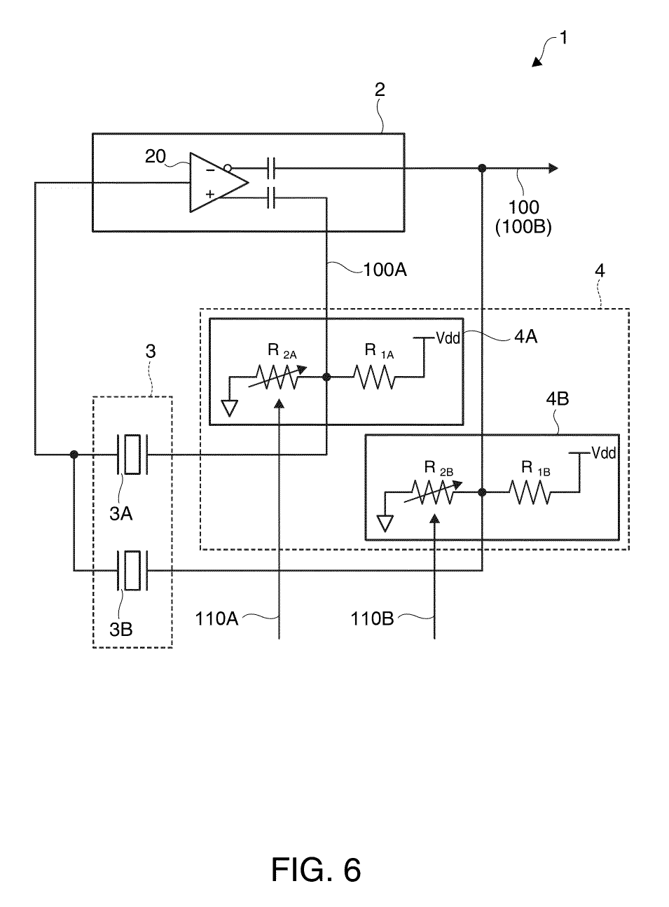

The vibratory device 1 according to the present embodiment can be realized by, for example, such a circuit configuration as shown in FIG. 6 using such a vibrator 3 as described above. As described above, it can be said that the vibrator 3 is configured including the two vibrators 3A, 3B (see FIG. 2). Further, by the vibrators 3A, 3B receiving the alternating-current signals 100A, 100B having the respective phases 180 degrees different from each other, the movable electrode having the fixed-fixed beam structure vibrates with a large amplitude in the Y-axis direction shown in FIG. 2.

The oscillator circuit 2 includes an inverter amplifier circuit 20, and outputs the alternating-current signals 100A, 100B having the phases 180 degrees different from each other via respective capacitors. Further, the oscillator circuit 2 outputs either one (e.g., the alternating-current signal 100B) of the alternating-current signals as the clock pulses 100 with the target frequency.

In order to regulate the resonant frequency of the vibrator 3 to a desired value, it is necessary to apply an appropriate bias voltage between the electrodes by the bias circuit 4. In the circuit configuration example shown in FIG. 6, the bias circuit 4 includes a first bias circuit 4A and a second bias circuit 4B each for applying the direct-current bias voltage between the electrodes using a resistive divider.

The first bias circuit 4A changes the value of a variable resistance R_{2A} in accordance with a control signal 110A to thereby regulate the direct-current bias voltage between the first movable electrode 41 (see FIG. 2) and the first stationary electrode 31 (see FIG. 2). Further, the second bias circuit 4B changes the value of a variable resistance R_{2B} in accordance with a control signal 110B to thereby regulate the direct-current bias voltage between the second movable electrode 42 (see FIG. 2) and the second stationary electrode 32 (see FIG. 2). It should be noted that the control signal 110A and the control signal 110B correspond to the control signal 110 shown in FIG. 1.

As described above, the vibratory device 1 according to the present embodiment is capable of regulating the resonant frequency by the bias circuit 4 (see FIG. 1) regulating the direct-current bias voltages to be applied between the movable electrode and the stationary electrodes. On this occasion, since the movable electrode and the stationary electrode do not form the parallel plate structure, the problem that the nonlinear action becomes conspicuous in accordance with the displacement of the movable electrode does not occur. Further, since the movable electrode and the stationary electrode attract each other, it is not required to separately provide an electrode for generating the tensile stress. In other words, the problem that the vibratory device 1 grows in size does not occur.

### 2. Modified Examples of First Embodiment

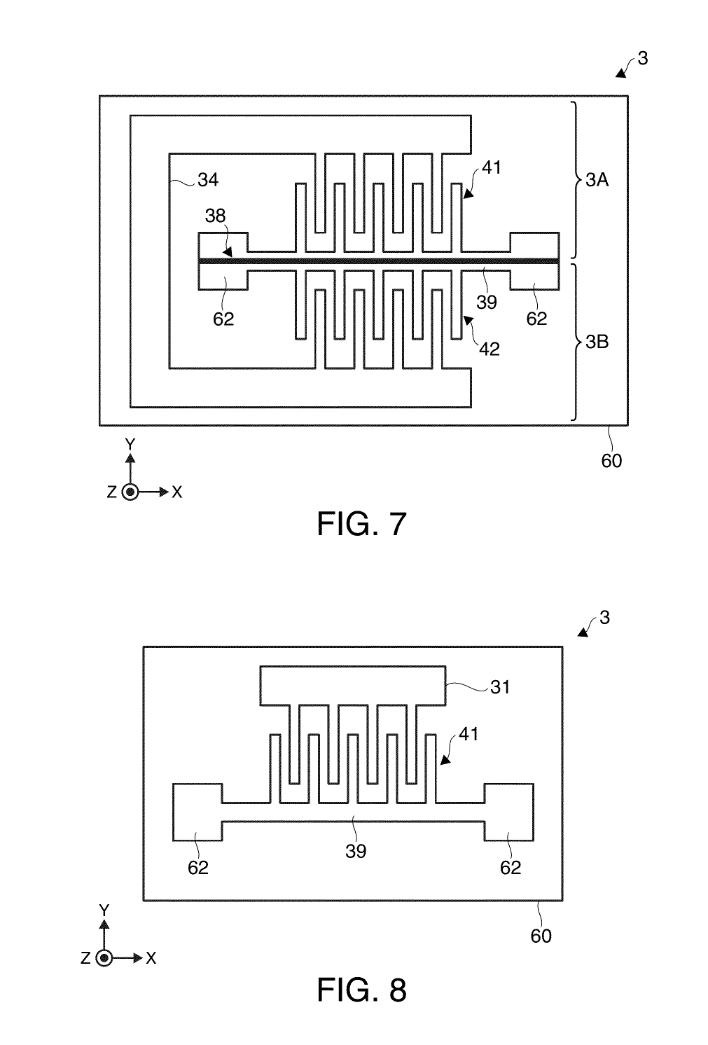

Hereinafter, some modified examples of the first embodiment will be explained with reference to FIGS. 7 through 9. It should be noted that the same components as those shown in FIGS. 1 through 6 are denoted with the same reference numerals and symbols, and the explanation thereof will be omitted. Further, regarding the vibratory device 1 according to the modified examples of the first embodiment, the block diagram is also the same as that of the first embodiment (FIG. 1), and the explanation thereof will be omitted.

### 2.1. First Modified Example

FIG. 7 is a plan view schematically showing the vibrator 3 of the vibratory device 1 according to a first modified example. The vibrator 3 of the present modified example has the first movable electrode 41 and the second movable electrode 42 electrically isolated from each other unlike the first embodiment. Specifically, the movable electrode is separated into two movable electrodes by an insulating body 38. On the other hand, a stationary electrode 34 is not separated into the first stationary electrode 31 (see FIG. 2) and the second stationary electrode 32 (see FIG. 2) as in the case of the first embodiment.

The present modified example corresponds to the case of exchanging the treatment of the stationary electrode and the treatment of the movable electrode in the first embodiment for each other. However, the point that the vibrator 3 is configured including the two vibrators 3A, 3B is the same as in the first embodiment, and therefore, the same circuit configuration (see FIG. 6) as in the first embodiment can be adopted. Further, similarly to the first embodiment, the vibratory device 1 according to the present modified example can achieve the frequency regulation without the nonlinear action of the movable electrode and without increasing the size of the vibratory device 1.

### 2.2. Second Modified Example

FIG. 8 is a plan view schematically showing the vibrator 3 of the vibratory device 1 according to a second modified example. The vibrator 3 of the present modified example has a pair of stationary electrode (the first stationary electrode 31) and movable electrode (the first movable electrode 41) alone unlike the first embodiment. In this case, the direct-current bias voltage between these electrodes is regulated by the bias circuit 4 (see FIG. 1) to thereby regulate the resonant frequency of the vibrator 3.

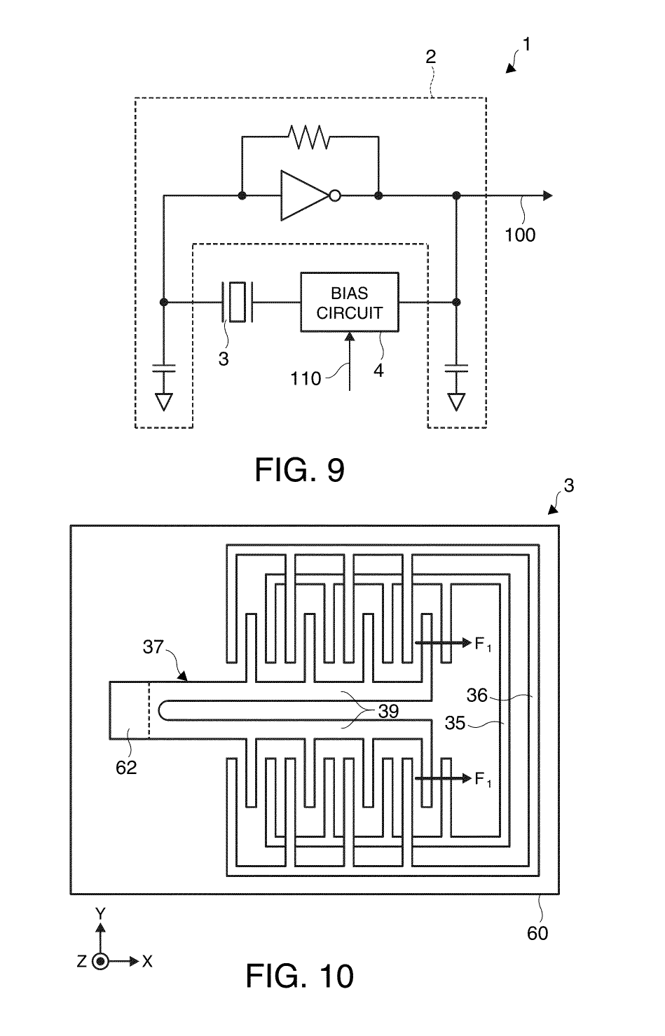

FIG. 9 is a diagram for explaining a circuit configuration example of the vibratory device 1 according to the present modified example. Unlike the first embodiment, the only one vibrator 3 is included, and the oscillator circuit 2 performs the phase regulation using an inverter and a feedback resistor. It should be noted that the bias circuit 4 can have the same circuit configuration as that of the first bias circuit 4A shown in FIG. 6.

Similarly to the first embodiment, the vibratory device 1 according to the present modified example can achieve the frequency regulation without the nonlinear action of the movable electrode. Further, although such a large vibration amplitude of the movable electrode as that of the first embodiment is not achievable, the vibratory device 1 according to the present modified example allows the circuit area of the vibrator 3 to be reduced, and therefore, the vibratory device 1 smaller in size can be realized.

### 3. Second Embodiment

A second embodiment will be explained with reference to FIGS. 10 through 13. It should be noted that the same components as those shown in FIGS. 1 through 9 are denoted with the same reference numerals and symbols, and the explanation thereof will be omitted. Further, regarding the vibratory device 1 according to the second embodiment, the block diagram is also the same as that of the first embodiment (FIG. 1), and the explanation thereof will be omitted.

FIG. 10 is a plan view schematically showing the vibrator 3 of the vibratory device 1 according to the present embodiment viewed from the positive direction of the Z axis. As shown in FIG. 10, the vibrator 3 is provided with a movable electrode 37 and stationary electrodes (a third stationary electrode 35 and a fourth stationary electrode 36) disposed above the substrate 60.

The movable electrode 37 is supported by the two beams 39 having elasticity and having one end fixed above the substrate 60 in the fixation portion 62. As shown in FIG. 10, the movable electrode 37 has a cantilever structure, and is provided with electrodes protruding from each of the beams 39 to form a comb-like shape. It should be noted that although in the present embodiment the movable electrode 37 has a tuning-fork structure having the two beams 39 vibrating in the respective directions opposite to each other so as to suppress the leakage of the vibration energy to the substrate 60, a structure having a single beam 39 can also be adopted.

The stationary electrode includes the third stationary electrode 35 and the fourth stationary electrode 36 fixed on the substrate 60. The third stationary electrode 35 and the fourth stationary electrode 36 are each provided with comb-like electrodes each extending toward the beams 39 and perpendicular to the longitudinal direction of the beams 39. The comb-like electrodes of the stationary electrodes are inserted between the comb-like electrodes of the movable electrode. Here, the comb-like electrodes of the third stationary electrode 35 are each inserted on the far side from the fixation portion 62 with respect to the comb-like electrodes of the movable electrode. In contrast, the comb-like electrodes of the fourth stationary electrode 36 are each inserted on the near side to the fixation portion 62 with respect to the comb-like electrodes of the movable electrode.

In the present embodiment, the third stationary electrode 35 and the fourth stationary electrode 36 are electrically isolated from each other, and the bias circuit 4 (see FIG. 1) includes a third bias circuit (not shown) and a fourth bias circuit (not shown) independent of each other, wherein the third bias circuit applies a direct-current bias voltage between the movable electrode 37 and the third stationary electrode 35, and the fourth bias circuit applies a direct-current bias voltage between the movable electrode 37 and the fourth stationary electrode 36. In this case, the third bias circuit and the fourth bias circuit are capable of applying the direct-current bias voltages in an independent manner.

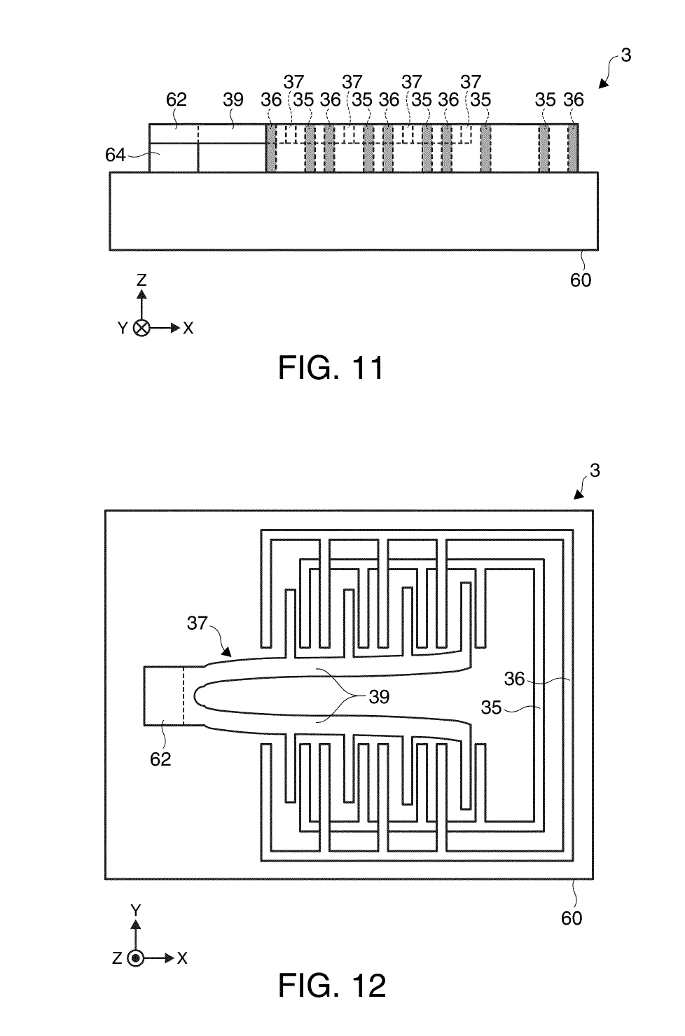

FIG. 11 is a side view schematically showing the vibrator 3 of the vibratory device 1 according to the present embodiment viewed from the negative direction of the Y axis. It should be noted that the comb-like electrodes are indicated by the dotted lines as a partially transparent view.

As shown in FIG. 11, the movable electrode 37 is disposed above the substrate 60 with a gap. The beams 39 for supporting the movable electrode 37 are integrated with the movable electrode 37, and one end fixed to the substrate 60 in the fixation portion 62 using the support member 64. As shown in FIG. 11, the movable electrode 37 has the gap corresponding to the height of the support member 64, and is therefore allowed to be displaced in response to the electrostatic force except the fixation portion 62.

The comb-like electrodes of the movable electrode 37 and the comb-like electrodes of the stationary electrodes (the third stationary electrode 35 and the fourth stationary electrode 36) are inserted alternately to each other as shown in FIG. 11 to thereby form a comb drive actuator having the movable electrode moving in accordance with the voltage applied between the electrodes.

Here, the comb-like electrodes of the third stationary electrode 35 are each inserted on the far side from the fixation portion 62 with respect to the comb-like electrodes of the movable electrode 37. Therefore, when applying a direct-current bias voltage between the movable electrode 37 and the third stationary electrode 35, the electrostatic force acts on the comb-like electrodes of the movable electrode 37 so as to approach the third stationary electrode 35. In other words, the electrostatic force (see F₁ in FIG. 10) acts on the comb-like electrodes of the movable electrode 37 in a direction (the positive direction of the X axis) of getting further from the fixation portion 62.

In contrast, the comb-like electrodes of the fourth stationary electrode 36 are each inserted on the near side to the fixation portion 62 with respect to the comb-like electrodes of the movable electrode 37. Therefore, when applying a direct-current bias voltage between the movable electrode 37 and the fourth stationary electrode 36, the electrostatic force acts on the comb-like electrodes of the movable electrode 37 so as to approach the fourth stationary electrode 36. In other words, the electrostatic force acts on the comb-like electrodes of the movable electrode 37 in a direction (the negative direction of the X axis) of getting closer to the fixation portion 62.

As described above, in the present embodiment, the bias circuit 4 (see FIG. 1) includes the third bias circuit and the fourth bias circuit independent of each other, wherein the third bias circuit applies the direct-current bias voltage (hereinafter referred to as a positive direction bias voltage) between the movable electrode 37 and the third stationary electrode 35, and the fourth bias circuit applies the direct-current bias voltage (hereinafter referred to as a negative direction bias voltage) between the movable electrode and the fourth stationary electrode 36. Therefore, although in the case in which the positive direction bias voltage and the negative direction bias voltage are equal to each other, the both bias voltages are balanced and canceled out each other, in the case in which the voltages are different from each other, the balance is broken, and the voltages act thereon so as to apply a tensile stress (the force acting in the positive direction of the X axis) or a compressive stress (the force acting in the negative direction of the X axis) to the beams 39 of the movable electrode 37. Using such characteristics, the resonant frequency of the movable electrode 37 can be changed.

Here, the vibration of the movable electrode 37 is substantially the same as that in the first embodiment. Specifically, by applying an alternating-current voltage to the third stationary electrode 35 and the fourth stationary electrode 36, the movable electrode vibrates in the Y direction at the resonant frequency.

FIG. 12 is a diagram schematically showing the vibration of the movable electrode 37 in the vibratory device 1 according to the present embodiment. The movable electrode 37 has the tuning-fork structure having the two beams 39 vibrating in the respective directions opposite to each other so as to suppress the leakage of the vibration energy to the substrate 60. Therefore, in this example, one (the upper one) of the beams 39 is displaced in the positive direction of the Y axis, while the other (the lower one) of the beams 39 is displaced in the negative direction of the Y axis. It should be noted that in this example, the positive direction bias voltage is greater than the negative direction bias voltage, and thus the electrostatic force indicated by F₁ in FIG. 10 acts on the beams 39. Therefore, the comb-like electrodes of the movable electrode 37 are steadily attracted toward the third stationary electrode 35, and thus the regulation of the resonant frequency is performed.

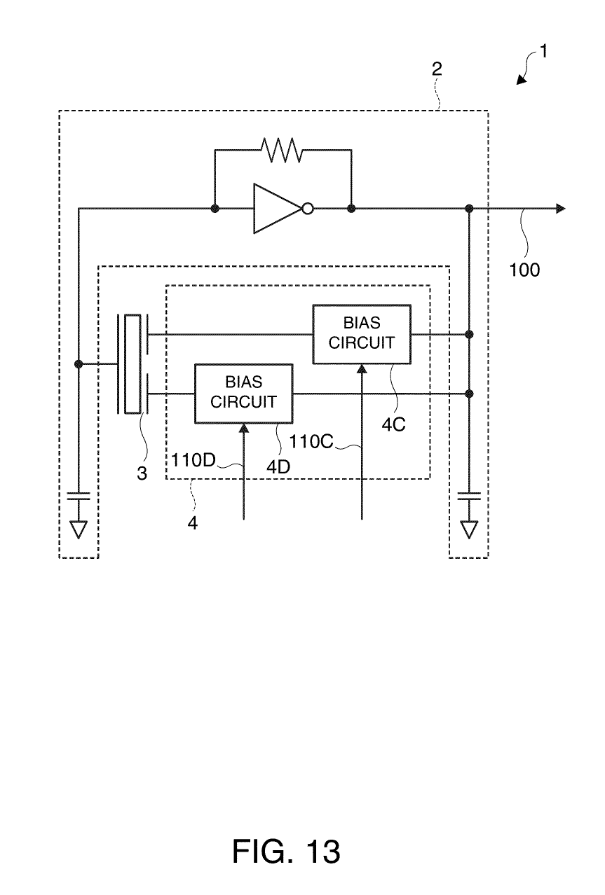

The vibratory device 1 according to the present embodiment can be realized by, for example, such a circuit configuration as shown in FIG. 13 using such a vibrator 3 as described above. As described above, it is possible to apply the direct-current bias voltage to the vibrator 3 by the third bias circuit 4C and the fourth bias circuit 4D as the two bias circuits independent of each other. The third bias circuit 4C and the fourth bias circuit 4D can be formed of resistive divider circuits (see FIG. 6) including variable resistances which can be regulated by control signals 110C, 110D, respectively, or other bias circuits (e.g., those using a transistor) can also be used. It should be noted that the oscillator circuit 2 is the same as shown in FIG. 9, and therefore, the explanation thereof will be omitted.

As described above, the vibratory device 1 according to the present embodiment is capable of regulating the resonant frequency by the bias circuit 4 regulating the direct-current bias voltages to be applied between the movable electrode and the stationary electrodes. On this occasion, since the movable electrode and the stationary electrode do not form the parallel plate structure, the problem that the nonlinear action becomes conspicuous in accordance with the displacement of the movable electrode does not occur. Further, since the movable electrode and the stationary electrode attract each other, it is not required to separately provide an electrode for generating the tensile stress. In other words, the problem that the vibratory device 1 grows in size does not occur.

### 4. Modified Example of Second Embodiment

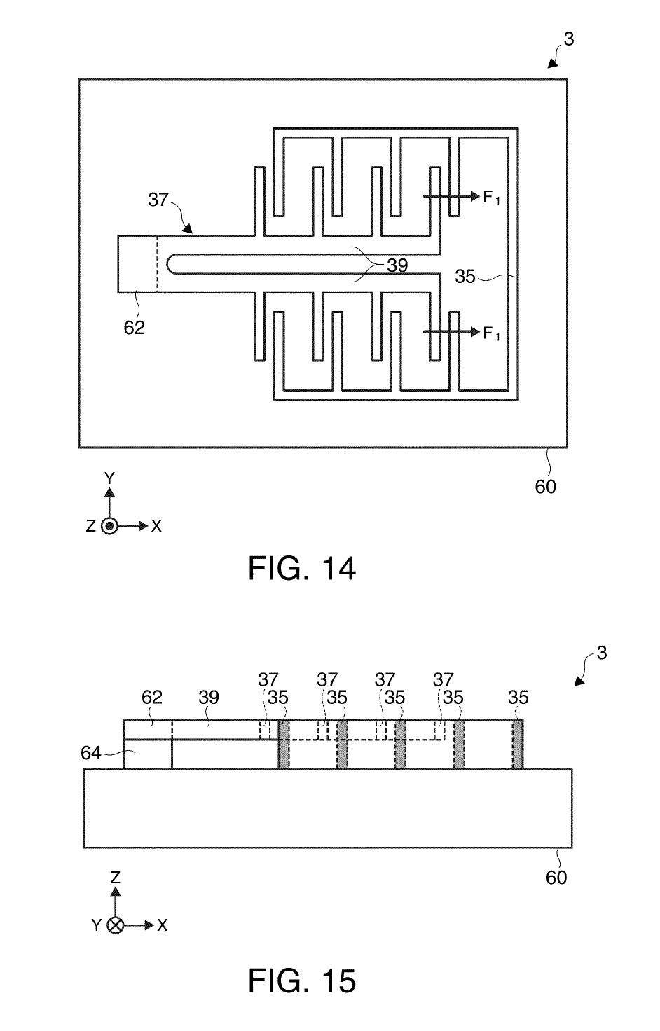

Hereinafter, a modified example of the second embodiment will be explained with reference to FIGS. 14 and 15. It should be noted that the same components as those shown in FIGS. 1 through 13 are denoted with the same reference numerals and symbols, and the explanation thereof will be omitted. Further, regarding the vibratory device 1 according to the modified example of the second embodiment, the block diagram is also the same as that of the first embodiment (FIG. 1), and the explanation thereof will be omitted.

FIG. 14 is a plan view schematically showing the vibrator 3 of the vibratory device 1 according to a third modified example as the modified example of the second embodiment. The vibrator 3 of the present modified example does not include the fourth stationary electrode 36 unlike the second embodiment. Therefore, the circuit structure becomes simpler than that of the vibrator 3 of the vibratory device 1 according to the second embodiment, and improvement of, for example, manufacturing yield can be expected.

FIG. 15 is a side view schematically showing the vibrator 3 of the vibratory device 1 according to the present modified example viewed from the negative direction of the Y axis. It should be noted that the comb-like electrodes are indicated by the dotted lines as a partially transparent view. Unlike the second embodiment, the comb-like electrodes of the third stationary electrode 35, each of which is inserted on the far side from the fixation portion 62 with respect to the comb-like electrodes of the movable electrode, exist alone. Therefore, the tensile stress (the force acting in the positive direction of the X axis) alone acts on the beams 39 of the movable electrode 37 due to the direct-current bias voltage applied by the bias circuit 4. It should be noted that the vibratory device 1 according to the present modified example can be realized by, for example, such a circuit configuration as shown in FIG. 9 using such a vibrator 3 as described above.

Similarly to the second embodiment, the vibratory device 1 according to the present modified example can achieve the frequency regulation without the nonlinear action of the movable electrode and without increasing the size of the vibratory device 1. It should be noted that in the vibratory device 1 according to the present modified example, since the tensile stress alone acts on to the movable electrode 37, the regulation range of the resonant frequency is not so large as in the second embodiment. However, as described above, the circuit structure becomes simple, and the improvement of, for example, the manufacturing yield can be expected.

### 5. Electronic Apparatuses

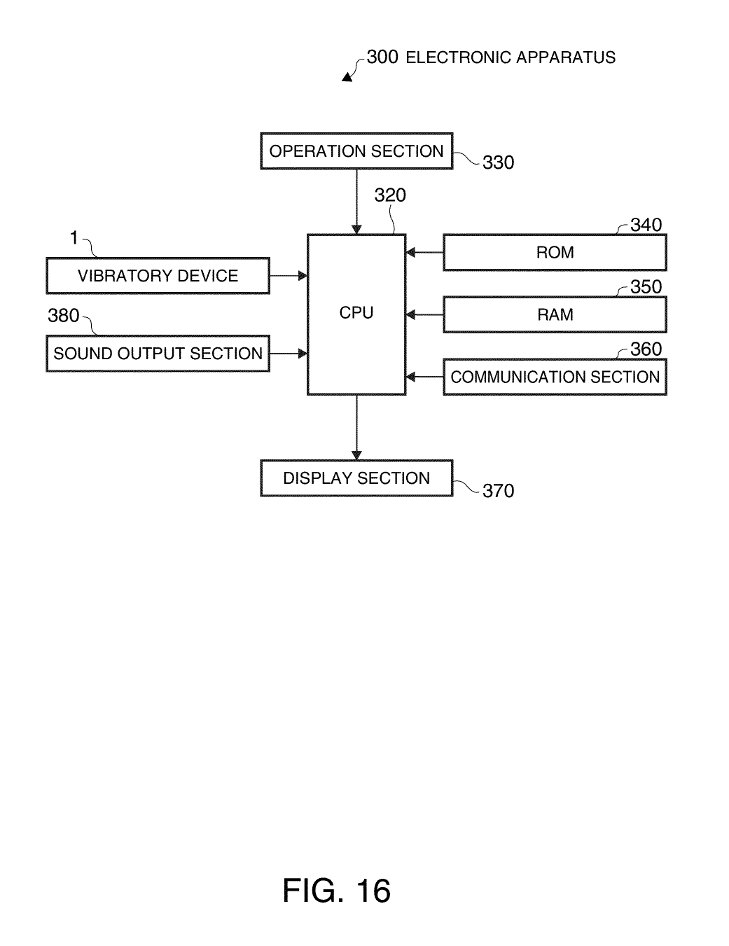

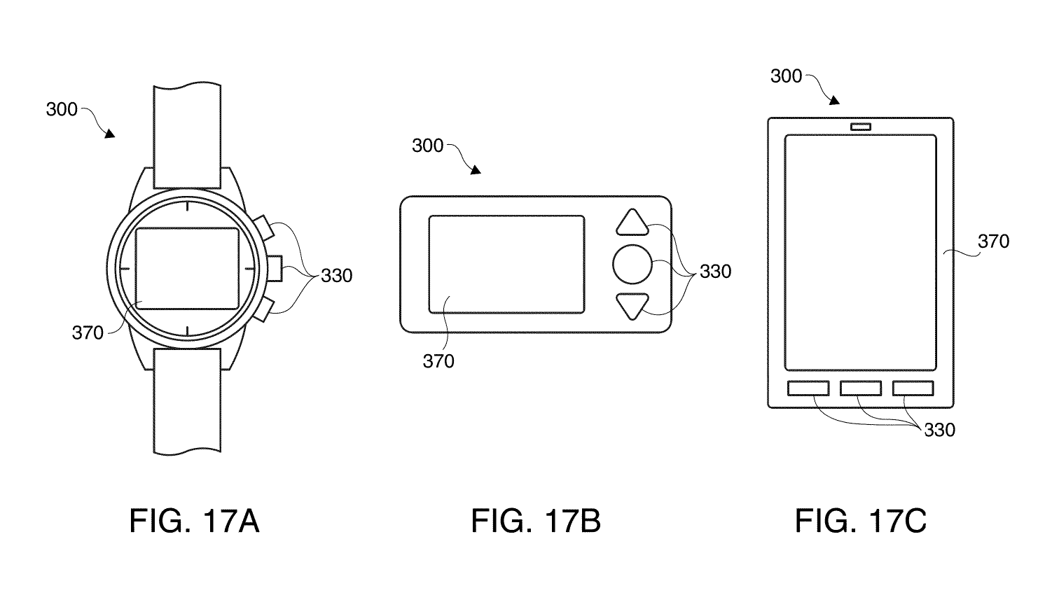

An electronic apparatus 300 as an application example of the first embodiment, the second embodiment, and the modified examples thereof will be explained with reference to FIGS. 16 and 17A through 17C. It should be noted that the same components as those shown in FIGS. 1 through 15 are denoted with the same reference numerals and symbols, and the explanation thereof will be omitted.

FIG. 16 is a functional block diagram of the electronic apparatus 300 according to the application example. The electronic apparatus 300 according to the present application example is configured including an vibratory device 1, a central processing unit (CPU) 320, an operation section 330, a read only memory (ROM) 340, a random access memory (RAM) 350, a communication section 360, a display section 370, and a sound output section 380. It should be noted that the electronic apparatus 300 according to the present application example can have a configuration obtained by eliminating or modifying some of the components (the sections) shown in FIG. 16, or adding another component to the configuration described above.

As described above, the vibratory device 1 is capable of outputting an oscillation signal (the clock pulses) with high accuracy obtained by correcting the variation in the resonant frequency caused in, for example, the manufacturing process with the direct-current bias voltage.

The CPU 320 performs a variety of arithmetic processes and control processes using the oscillation signal (the clock pulses) output by the vibratory device 1 in accordance with the program stored in the ROM 340 and so on. Specifically, the CPU 320 performs a variety of processes corresponding to the operation signal from the operation section 330, a process of controlling the communication section 360 for performing data communication with external devices, a process of transmitting a display signal for making the display section 370 display a variety of types of information, a process of making the sound output section 380 output a variety of sounds, and so on.

The operation section 330 is an input device including operation keys, button switches, and so on, and outputs the operation signal corresponding to the operation by the user to the CPU 320.

The ROM 340 stores a program, data, and so on for the CPU 320 to perform a variety of arithmetic processes and control processes.

The RAM 350 is used as a working area of the CPU 320, and temporarily stores, for example, the program and data retrieved from the ROM 340, the data input from the operation section 330, and the calculation result obtained by the CPU 320 performing operations with the various programs.

The communication section 360 performs a variety of control processes for achieving the data communication between the CPU 320 and the external devices.

The display section 370 is a display device formed of a liquid crystal display (LCD) or the like, and displays a variety of information based on a display signal input from the CPU 320.

The sound output section 380 is a device for outputting sounds such as a speaker.

According to the electronic apparatus 300 according to the present application example, the clock pulses with an accurate frequency can be obtained by the vibratory device 1. Therefore, it becomes possible for the CPU 320 or the like to accurately perform a variety of types of arithmetic processes and control processes. Further, the vibratory device 1 can be miniaturized, and can therefore be applied to a portable device and so on for an performing advanced arithmetic process.

FIGS. 17A, 17B, and 17C are diagrams each showing an example of an appearance of the electronic apparatus 300. The electronic apparatus 300 can be a watch shown in FIG. 17A, or a portable navigation terminal shown in FIG. 17B. Alternatively, the electronic apparatus 300 can be a smartphone, a cellular phone, or the like shown in FIG. 17C. It should be noted that the buttons or the like shown in FIGS. 17A through 17C correspond to the operation section 330, and liquid crystal screen or the like corresponds to the display section 370.

The watch shown in FIG. 17A needs the clock pulses with an accurate frequency in order to accurately display the time. Further, the portable navigation terminal shown in FIG. 17B needs the clock pulses with an accurate frequency in order to indicate the accurate position of the user using the Global Positioning System (GPS). Further, the smartphone shown in FIG. 17C needs the clock pulses with the accurate frequency used for the communication. Moreover, these devices are portable equipment, and are therefore required to be small in size. The electronic apparatus 300 according to the present application example uses the vibratory device 1, and is therefore capable of fulfilling these requirements.

### 6. Other Issues

The invention is not limited to the embodiments and the modified examples described above, but can be put into practice with various modifications within the scope or the spirit of the invention. In other words, the embodiments and the modified examples described above are illustrative only, and the invention is not limited to the embodiments and the modified examples. For example, it is also possible to arbitrarily combine the embodiments and the modified examples described above with each other. For example, it is also possible to adopt a configuration in which the CPU 320 is provided with the function as the frequency regulation section, and generates the control signal 110, or the independent frequency regulation section can be included in the vibratory device 1.

The invention includes configurations (e.g., configurations having the same function, the same way, and the same result, or configurations having the same object and the same advantage) substantially the same as the configuration described as one of the embodiments of the invention. Further, the invention includes configurations obtained by replacing a non-essential part of the configuration described as one of the embodiments. Further, the invention includes configurations providing the same functions and the same advantage, or configurations capable of achieving the same object, as the configuration described as one of the embodiments. Further, the invention includes configurations obtained by adding a known technology to the configuration described as one of the embodiments.

The entire disclosure of Japanese Patent Application No. 2012-145110, filed Jun. 28, 2012 is expressly incorporated by reference herein.

What is claimed is:

1. A vibratory device comprising:
a vibrator including
a beam, which can be displaced,
a movable electrode having a comb-like shape, the comb teeth extending from the beam, and
a stationary electrode having a comb-like shape, each of the comb teeth being inserted between the comb-like electrodes of the movable electrode;
an oscillator circuit adapted to make the vibrator oscillate; and
a bias circuit adapted to apply a direct-current bias voltage between the movable electrode and the stationary electrode.

2. The vibratory device according to claim 1, wherein
the movable electrode includes
a first movable electrode having a comb-like shape disposed on one side of the beam in a plan view, and
a second movable electrode having a comb-like shape disposed on the other side of the beam,
the stationary electrode includes
a first stationary electrode having a comb-like shape, each of the comb teeth being inserted between the comb teeth of the first movable electrode, and
a second stationary electrode having a comb-like shape, each of the comb teeth being inserted between the comb teeth of the second movable electrode, and
the bias circuit includes
a first bias circuit adapted to apply a direct-current bias voltage between the first movable electrode and the first stationary electrode, and
a second bias circuit adapted to apply a direct-current bias voltage between the second movable electrode and the second stationary electrode.

3. The vibratory device according to claim 2, wherein
in the vibrator
the first movable electrode and the second movable electrode of the movable electrode are electrically connected to each other, and
the first stationary electrode and the second stationary electrode of the stationary electrode are electrically isolated from each other.

4. The vibratory device according to claim 2, wherein
in the vibrator
the first movable electrode and the second movable electrode of the movable electrode are electrically isolated from each other, and
the first stationary electrode and the second stationary electrode of the stationary electrode are electrically connected to each other.

5. The vibratory device according to claim 1, wherein both ends of the beam of the vibrator are fixed.

6. A vibratory device comprising:
a vibrator including
a beam having one end fixed and the other end displaceable,
a movable electrode having a comb-like shape, the comb teeth extending from the beam, and
a stationary electrode having a comb-like shape, each of the comb teeth being inserted between the comb-like electrodes of the movable electrode;
an oscillator circuit adapted to make the vibrator oscillate; and
a bias circuit adapted to apply a direct-current bias voltage between the movable electrode and the stationary electrode,
wherein the stationary electrode includes a third stationary electrode disposed on one side of an electrode constituting the movable electrode.

7. The vibratory device according to claim 6, wherein
the stationary electrode includes a fourth stationary electrode disposed on the other side of the electrode constituting the movable electrode,
the third stationary electrode and the fourth stationary electrode are electrically isolated from each other, and
the bias circuit includes
a third bias circuit adapted to apply a direct-current bias voltage between the movable electrode and the third stationary electrode, and
a fourth bias circuit adapted to apply a direct-current bias voltage between the movable electrode and the fourth stationary electrode.

8. An electronic apparatus comprising:
the vibratory device according to claim 1.

9. An electronic apparatus comprising:
the vibratory device according to claim 6.
